(19) United States
(12) Patent Application Publication
(10) Pub. No.: US 2026/0243657 A1
(43) Pub. Date: Aug. 20, 2026

(54) METHOD FOR MEASURING PEEL STRENGTH OF METAL-BONDED CERAMIC SUBSTRATE, METHOD FOR MANUFACTURING METAL-BONDED CERAMIC SUBSTRATE, AND METAL BONDED CERAMIC SUBSTRATE MANUFACTURED THEREBY

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 19/164,959

(22) PCT Filed: Feb. 29, 2024
(86) PCT No.: PCT/KR2024/002629

§ 371 Date: Sep. 12, 2025

(30) Foreign Application Priority Data
Mar. 15, 2023 (KR) 10-2023-0033903

(51) Int. Cl. G01N 19/04; H05K 3/06

(52) U.S. Cl. CPC G01N 19/04; H05K 3/06; H05K 2203/162

(57) ABSTRACT

A metal-bonded ceramic substrate according to an embodiment of the present invention has metal layers bonded to the surface thereof so as to form circuit patterns, and has a plurality of the circuit patterns arranged in columns and rows, wherein, when the circuit patterns are formed, a dummy pattern for measuring peel strength can also be formed in at least one from among a plurality of dummy areas, which encompass a circuit pattern area.

### TECHNICAL FIELD

Embodiments of the present disclosure relate to a method for measuring peel strength of a metal-bonded ceramic substrate for peel strength measurement of a metal circuit layer and a ceramic material, a method for manufacturing the metal-bonded ceramic substrate, and the metal-bonded ceramic substrate manufactured thereby.

### BACKGROUND ART

Power modules for electric vehicles mainly use ceramic substrates as substrates for transmitting power to inverters, converters, and OBCs, and circuit substrates.

The ceramic substrate is a heterojunction substrate in which a metal circuit layer of copper (Cu) or aluminum (Al) is bonded to a ceramic material such as Al₂O₃, ZTA, AlN, Si₃N₄, or SiC. Processes for heterojunction of the ceramic material and the metal circuit layer include DBC, AMB, and the like, and in particular, an AMB bonding method using an active material is applied to a power semiconductor field requiring high reliability.

Recently, as high-power power modules are used, since more heat dissipation and strong mechanical bonding properties (peel strength) are required, mechanical bonding properties were evaluated by producing separate samples for peel strength evaluation in the related art. However, since the results of the bonding property evaluation in the related art are merely values representing a unit lot and are not obtained by actually measuring peel strength of each ceramic substrate, the peel strength of an actual product is not guarantable to reduce reliability and additional costs are incurred for designing and producing separate samples for peel strength evaluation, resulting in inefficiency.

The contents described in the Background Art are to help the understanding of the background of the disclosure, and may include contents that are not a disclosed conventional technology. CL DISCLOSURE

### TECHNICAL PROBLEM

The present disclosure has been proposed in consideration of the aforementioned circumstances, and an object of the present disclosure is to provide a method for measuring peel strength of a metal-bonded ceramic substrate, a method for manufacturing the metal-bonded ceramic substrate, and the metal-bonded ceramic substrate manufactured thereby, which enable evaluation of peel strength of an actual product without producing a separate sample for peel strength measurement in measuring the peel strength of a metal circuit layer and a ceramic material of a ceramic substrate.

### Technical Solution

A method for measuring peel strength of a metal-bonded ceramic substrate according to embodiments of the present disclosure may include: providing a metal-bonded ceramic substrate including a circuit pattern area where a plurality of circuit patterns are disposed in rows and columns and a plurality of dummy areas encompassing the circuit pattern area, a dummy pattern for measuring peel strength being formed in at least one of the dummy areas; separating at least one of the dummy areas; and measuring peel strength of the dummy pattern formed in the separated dummy area.

In the measuring of the peel strength of the dummy pattern, a remaining portion of the separated dummy area except for the dummy pattern may be fixed, and the dummy pattern may be peeled off while being pulled with a measuring machine to measure the peel strength of the dummy pattern.

In the separating of the dummy areas, the dummy areas may be separated along a cutting line formed around the dummy areas.

In the providing of the metal-bonded ceramic substrate, the dummy pattern may be disposed to cross a central portion of the dummy area.

In the providing of the metal-bonded ceramic substrate, the dummy pattern may be formed in a bar shape.

In the providing of the metal-bonded ceramic substrate, the dummy pattern may have a length of 100 mm or more and a width of 2 mm or more.

In the providing of the metal-bonded ceramic substrate, a first cutting line may be formed between the circuit patterns, and between the circuit pattern and the dummy area.

In the providing of the metal-bonded ceramic substrate, a second cutting line may be formed on both sides of the dummy area, and may be a portion corresponding to an extension line of a boundary between the circuit pattern and the dummy area.

A method for manufacturing a metal-bonded ceramic substrate according to embodiments of the present disclosure may include: providing a ceramic material; and forming a plurality of circuit patterns in rows and columns on at least one surface of the ceramic material and forming a dummy pattern in at least one of a plurality of dummy areas encompassing an area where the circuit patterns are formed, wherein in the forming of the dummy pattern, when the circuit pattern is formed in the area where the circuit patterns are formed, the dummy pattern for measuring peel strength may be formed together in at least one of the plurality of dummy areas.

In the forming of the dummy pattern, the dummy pattern may be disposed to cross a central portion of the dummy area.

In the forming of the dummy pattern, the dummy pattern may be formed in a bar shape.

In the forming of the dummy pattern, the dummy pattern may have a length of 100 mm or more and a width of 2 mm or more.

The forming of the dummy pattern may include: bonding a metal layer to at least one surface of the ceramic material; and forming the circuit patterns and the dummy pattern by etching the metal layer.

The forming of the circuit patterns and the dummy pattern may include forming a photoresist pattern on an upper surface of the metal layer; and etching the metal layer by using the photoresist pattern as an etching mask.

A metal-bonded ceramic substrate according to embodiments of the present disclosure is a metal-bonded ceramic substrate including metal layers bonded to a surface of the metal-bonded ceramic substrate to form a plurality of circuit patterns disposed in rows and columns, wherein, when the circuit patterns are formed, a dummy pattern for measuring peel strength may be formed together in at least one of a plurality of dummy areas encompassing an area where the circuit patterns are formed.

The dummy pattern may be disposed to cross a central portion of the dummy area. The dummy pattern may be formed in a bar shape and may have a length of 100 mm or more and a width of 2 mm or more.

In addition, in the metal-bonded ceramic substrate according to embodiments of the present disclosure, a first cutting line may be formed between the circuit patterns, and between the circuit pattern and the dummy area, and a second cutting line may be formed on both sides of the dummy area and may be a portion corresponding to an extension line of a boundary between the circuit pattern and the dummy area.

### Advantageous Effects

In accordance with a method for measuring peel strength of a metal-bonded ceramic substrate, a method for manufacturing the metal-bonded ceramic substrate, and the metal-bonded ceramic substrate manufactured thereby, reliable peel strength evaluation is possible by directly evaluating peel strength of an actual product by using an edge or a dummy portion of the actual product.

In accordance with a method for measuring peel strength of a metal-bonded ceramic substrate, a method for manufacturing the metal-bonded ceramic substrate, and the metal-bonded ceramic substrate manufactured thereby, cost reduction is possible and efficiency is high because no separate sample for peel strength evaluation is produced.

In accordance with a method for measuring peel strength of a metal-bonded ceramic substrate, a method for manufacturing the metal-bonded ceramic substrate, and the metal-bonded ceramic substrate manufactured thereby, availability can be improved and cost can be significantly reduced because a dummy pattern for peel strength measurement is formed in a dummy area that is a portion discarded without being used for a power module.

### DESCRIPTION OF DRAWINGS

FIG. 1 is a plan view illustrating a metal-bonded ceramic substrate according to embodiments of the present disclosure.

FIG. 2 is a partially enlarged view illustrating a part of the metal-bonded ceramic substrate according to embodiments of the present disclosure.

FIG. 3 is a plan view illustrating a first dummy area in the metal-bonded ceramic substrate according to embodiments of the present disclosure.

FIG. 4 is a flowchart showing a method for manufacturing the metal-bonded ceramic substrate according to embodiments of the present disclosure.

FIG. 5 is a view for describing a step of forming a dummy pattern in the method for manufacturing the metal-bonded ceramic substrate according to embodiments of the present disclosure.

FIG. 6 is a photograph for describing a method for measuring peel strength of the metal-bonded ceramic substrate according to embodiments of the present disclosure.

FIG. 7 is a plan view illustrating a ceramic substrate in which a plurality of test pattern portions are formed for peel strength measurement in the related art.

### MODE FOR INVENTION

Hereinafter, preferred embodiments of the present disclosure are described in detail with reference to the accompanying drawings.

Embodiments are provided to more fully explain the present disclosure to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of the embodiments, when it is described that each layer (film), area, pattern, or structure is formed “on” or “under” each substrate, layer (film), area, pad, or pattern, this includes both expressions, including that a layer is formed on another layer “directly” or “with a third layer interposed between the two layers (indirectly)”. Furthermore, a criterion for the term “on or under each layer” is described based on the drawings.

The drawings are merely for enabling the spirit of the present disclosure to be understood, and it should not be interpreted that the scope of the present disclosure is limited by the drawings. Furthermore, in the drawings, a relative thickness or length or a relative size may be enlarged for convenience and the clarity of description.

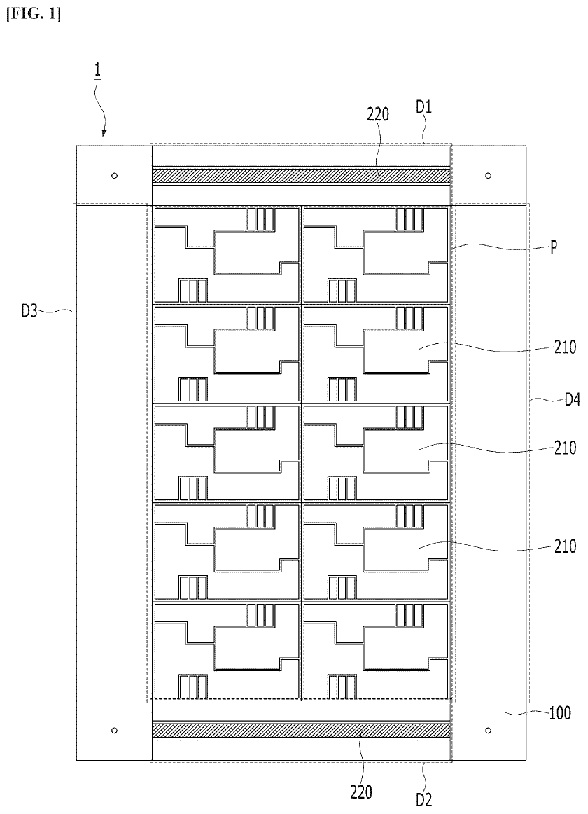

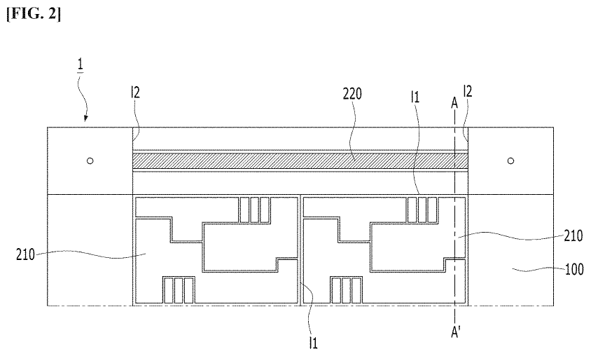

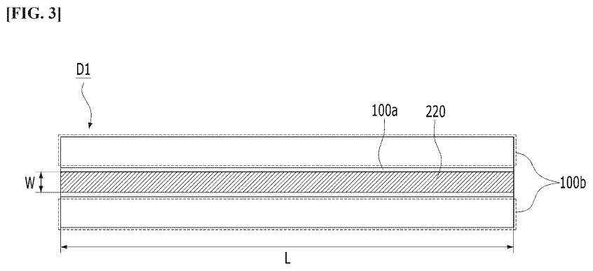

FIG. 1 is a plan view illustrating a metal-bonded ceramic substrate according to embodiments of the present disclosure, FIG. 2 is a partially enlarged view illustrating a part of the metal-bonded ceramic substrate according to embodiments of the present disclosure, and FIG. 3 is a plan view illustrating a first dummy area in the metal-bonded ceramic substrate according to embodiments of the present disclosure.

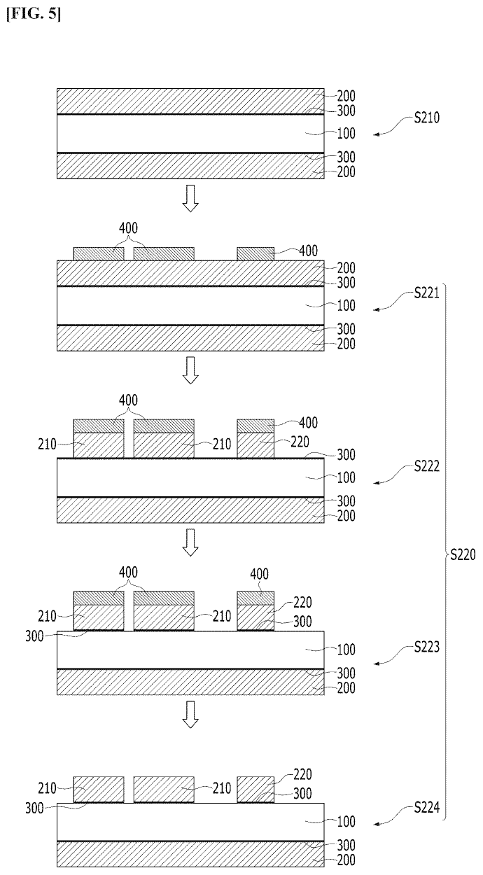

As illustrated in FIG. 1, a metal-bonded ceramic substrate 1 according to embodiments of the present disclosure is formed in the size (140 mm×190 mm) of a master card, and may include a plurality of circuit patterns 210 disposed in rows and columns, and dummy patterns 220 formed around the circuit patterns 210. The ceramic substrate is patterned with the circuit patterns 210 and the dummy patterns 220 after a metal layer 200 is bonded to at least one surface of a ceramic material 100, and as will be described below with reference to FIG. 5, the metal layer 200 may be bonded to at least one surface of the ceramic material 100 via a brazing filler 300. In this way, the present embodiment is described using an active metal brazing (AMB) substrate, which is most suitable in terms of durability and heat dissipation efficiency, as an example; however, a direct bonding copper (DBC) substrate may also be applied.

The plurality of circuit patterns 210 can be disposed in rows and columns in a circuit pattern area P that is the central portion of the metal-bonded ceramic substrate 1. The dummy pattern 220 can be formed in at least one of first to fourth dummy areas D1 to D4 disposed on the peripheral portion of the ceramic substrate where the circuit pattern 210 is not formed. In such a case, the dummy pattern 220 can be disposed to cross the central portion of at least one of the first to fourth dummy areas D1 to D4, and can be formed in a bar shape. The shape of such a dummy pattern 220 is to measure peel strength by using a measuring machine 20 to be described below. Since the measuring machine 20 measures the peel strength of the dummy pattern 220 by pulling the dummy pattern 220 at a constant speed and peeling off the dummy pattern 220, the dummy pattern 220 is preferably formed in the shape of a bar that crosses the center of the dummy areas D1 to D4 so that a part of the dummy pattern 220 can be easily peeled off at a constant speed while fixing a portion where the dummy pattern 220 is not formed.

In general, the peripheral areas of the ceramic substrate, that is, the dummy areas D1 to D4, are not actually used for a power module, etc., but are a portion provided to increase the rigidity of the ceramic substrate and are a portion that is discarded after the circuit pattern area P is cut. In order to utilize the discarded dummy areas D1 to D4, the present disclosure forms the dummy pattern 220 in at least one of the dummy areas D1 to D4 and enables accurate measurement of the peel strength of an actual product through the dummy pattern 220.

Referring to FIG. 2, a first cutting line I1 can be formed between the circuit patterns 210, and between the circuit pattern 210 and the dummy areas D1 to D4. In addition, a second cutting line I2 can be formed on both sides of the dummy areas D1 to D4. The first cutting line I1 can be formed to easily cut each of the circuit patterns 210, and the second cutting line I2 can be formed to easily cut each of the dummy areas. The second cutting line I2 may be a portion corresponding to an extension line of a boundary between the circuit pattern 210 and the dummy areas D1 to D4.

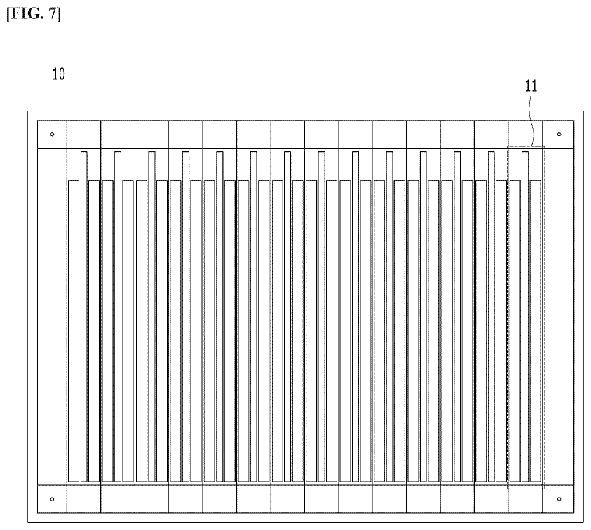

As illustrated in FIG. 7, in the related art, a ceramic substrate 10 having a plurality of test pattern portions 11 formed for peel strength measurement was separately produced, the plurality of test pattern portions 11 were cut to measure peel strength for each sample, and then the average of measured values was calculated to ascertain the peel strength. However, since this value is not measured from an actual product, the peel strength of the actual product is not guarantable, resulting in a problem of low reliability. In addition, it was inefficient because additional costs were incurred in manufacturing the ceramic substrate 10 having the plurality of test pattern portions 11 formed thereon.

In order to solve the above problem, in the present disclosure, when the circuit pattern 210 is formed, the dummy pattern 220 for measuring the peel strength is formed together in at least one of the plurality of dummy areas D1 to D4 encompassing the circuit pattern area P. In the present embodiment, the dummy pattern 220 is formed by etching the metal layer 200 of the first and second dummy areas D1 and D2 encompassing the circuit pattern area P together when the metal layer 200 of the circuit pattern area P is etched in order to form the circuit pattern 210. Since the dummy pattern 220 is formed with the same metal layer 200 as the circuit pattern 210, it is possible to actually measure the peel strength of the ceramic substrate product to which different materials are bonded, and thus the reliability of a measured value can be increased. In this way, in the metal-bonded ceramic substrate 1 according to embodiments of the present disclosure, the dummy pattern 220 is formed in at least one of the dummy areas D1 to D4 discarded after the circuit pattern area P is cut and can be utilized as a part for measuring the peel strength by pulling the dummy pattern 220 with a measuring machine and peeling off the dummy pattern 220, and a separate test pattern needs not be produced, which is cost-effective.

The present embodiment describes an example in which the dummy pattern 220 is formed in the first dummy area D1 and the second dummy area D2 among the first to fourth dummy areas D1 to D4 encompassing the circuit pattern area P; however, the present disclosure is not limited thereto and the dummy pattern 220 may also be formed in each of the first to fourth dummy areas D1 to D4.

In addition, although the present embodiment describes an example in which the dummy pattern 220 is formed on the metal layer 200 bonded to an upper surface of the ceramic material 100, the dummy pattern 220 can also be formed on the metal layer 200 bonded to a lower surface of the ceramic material 100. That is, the dummy pattern 220 can be formed by etching the metal layer 200 of at least one of the dummy areas D1 to D4 encompassing the circuit pattern area P together when the circuit pattern 210 is formed by etching the metal layer 200 bonded to the lower surface of the ceramic material 100. In such a case, since the dummy pattern 220 is formed with the same metal layer 200 as the circuit pattern 210, it is possible to measure the peel strength of the circuit pattern 210 formed on the lower surface of the ceramic material 100.

As illustrated in FIG. 3, the dummy pattern 220 is preferably formed to have a certain size or more in order to measure the peel strength by using the measuring machine 20 to be described below, and when the length L of the dummy pattern 220 is 100 mm or more and the width W thereof is 2 mm or more, the peel strength can be easily measured. In such a case, the thickness of the dummy pattern 220 may be 0.3 t or more.

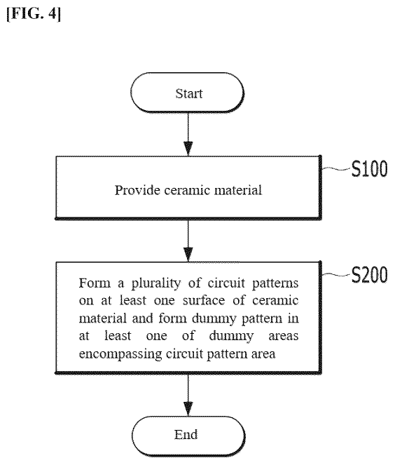

FIG. 4 is a flowchart showing a method for manufacturing the metal-bonded ceramic substrate according to embodiments of the present disclosure, and FIG. 5 is a view illustrating a cross section taken along line A-A′ in FIG. 2 in order to describe a step of forming a dummy pattern in the method for manufacturing the metal-bonded ceramic substrate according to embodiments of the present disclosure.

As illustrated in FIG. 4, the method for manufacturing the metal-bonded ceramic substrate according to embodiments of the present disclosure may include step S100 of providing the ceramic material 100, and step S200 of forming the plurality of circuit patterns 210 in rows and columns on at least one surface of the ceramic material 100 and forming the dummy pattern 220 in at least one of the plurality of dummy areas D1 to D4 encompassing an area where the circuit patterns 210 are formed.

In step S100 of providing the ceramic material 100, the ceramic material 100 may be made of any one of Al₂O₃, AlN, Si₃N₄, and zirconia toughened alumina (ZTA).

As illustrated in FIG. 5, step S200 of forming the dummy pattern 220 may include step S210 of bonding the metal layer 200 to at least one surface of the ceramic material 100, and step S220 of forming the circuit patterns 210 and the dummy pattern 220 by etching the metal layer 200.

In step S210 of bonding the metal layer 200, the metal layer 200 can be bonded to the upper and lower surfaces of the ceramic material 100 via the brazing filler 300. The metal layer 200 can be a metal such as Cu or Al. Step S210 of bonding the metal layer 200 may include a step of disposing the brazing filler 300 between at least one surface of the ceramic material 100 and the metal layer 200, and a step of melting the brazing filler 300 to bond the ceramic material 100 and the metal layer 200. In the step of disposing the brazing filler 300, the brazing filler 300 can be a material including at least one of Ag, Cu, AgCu, AgCuTi, and BAg₈, and can be disposed on the upper and lower surfaces of the ceramic material 100 by any one of plating, paste application, and foil attachment. In such a case, the thickness of the brazing filler 300 may be 0.3 μm to 3.0 μm. In the step of melting the brazing filler 300 to bond the ceramic material 100 and the metal layer 200, the brazing process can be performed in a bonding facility such as a brazing furnace, a vacuum furnace, or a continuous reduction brazing furnace, and can be performed at 450° C. or higher, preferably 780° C. to 900° C.

Step S220 of forming the circuit pattern 210 and the dummy pattern 220 may include step S221 of forming a photoresist pattern 400 on an upper surface of the metal layer 200, step S222 of etching the metal layer 200 by using the photoresist pattern 400 as an etching mask, step S223 of etching the brazing filler 300 exposed by etching the metal layer 200 until the upper surface of the ceramic material 100 is exposed, and step S224 of removing the photoresist pattern 400 through dry or wet etching.

In step S221 of forming the photoresist pattern 400, the photoresist pattern 400 can be formed by performing a photolithography process on the metal layer 200. Although not illustrated in detail, the photolithography process can form a photoresist layer on the metal layer 200, and then perform an exposure and development process on the photoresist layer to form the photoresist pattern 400. The photoresist pattern 400 can be formed as a pattern corresponding to the circuit pattern 210 and the dummy pattern 220 in order to form the circuit pattern 210 and the dummy pattern 220.

After step S221 of forming the photoresist pattern 400, step S222 of etching the metal layer 200 by using the photoresist pattern 400 as an etching mask can be performed. In step S222 of etching the metal layer 200, only a portion of the metal layer 200 where the photoresist pattern 400 is not formed can be removed through an etching process. The etching process may employ wet etching using an etchant solution such as HCl, HNO₃, H₃PO₄, or other organic surfactants, or dry etching using a laser, etc.

As the metal layer 200 is etched, the brazing filler 300 can be exposed at the etched portion of the metal layer 200. In order to remove the exposed brazing filler 300, step S223 of etching the exposed brazing filler 300 until the upper surface of the ceramic material 100 is exposed can be performed. In such a case, a material formed by a reaction between the ceramic material 100 and the brazing filler 300 may also be etched together. For example, when the ceramic material 100 is a nitride-based material such as AlN or Si₃N₄, since TiN may be formed by reacting with Ti of the brazing filler 300, TiN may also be etched together. Subsequently, by performing step S224 of removing the photoresist pattern 400 through dry or wet etching, the circuit patterns 210 separated from each other according to the designed pattern and the dummy pattern 220 around the circuit pattern 210 can be formed.

In this way, when the metal layer 200 is bonded to the ceramic material 100 during the manufacturing of the ceramic substrate and then the desired circuit pattern 210 is implemented through etching, a plurality of arranged circuit substrates can be manufactured at the same time, and can be finally cut into individual products through a laser scribing process using carbon dioxide, etc., and used. In addition, in the present disclosure, since the dummy pattern 220 is also formed together when the circuit pattern 210 is formed, it is possible to accurately measure the peel strength for the circuit pattern 210 of an actual product through the dummy pattern 220.

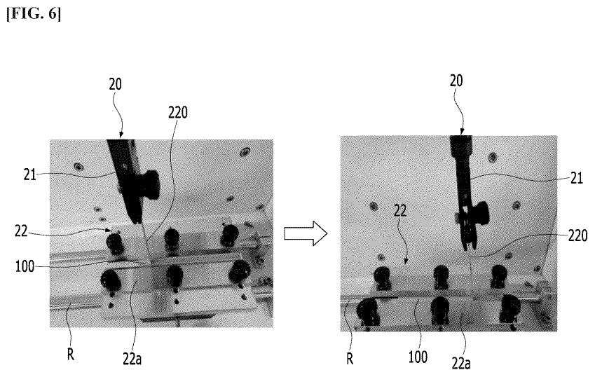

FIG. 6 is a photograph for describing a method for measuring the peel strength of the metal-bonded ceramic substrate according to embodiments of the present disclosure.

The method for measuring the peel strength of the metal-bonded ceramic substrate 1 according to embodiments of the present disclosure may include a step of providing the metal-bonded ceramic substrate 1, a step of separating at least one of the dummy areas D1 to D4 along the cutting lines I1 and I2 formed around the dummy areas D1 to D4, and a step of measuring the peel strength of the dummy pattern 220 formed in the separated dummy areas D1 to D4.

The step of providing the metal-bonded ceramic substrate 1 can provide the metal-bonded ceramic substrate 1 including the circuit pattern area P in which the plurality of circuit patterns 210 are disposed in rows and columns and the plurality of dummy areas D1 to D4 encompassing the circuit pattern area P, and having the dummy pattern 220 formed on at least one of the dummy areas D1 to D4 to measure the peel strength, as illustrated in FIG. 1.

The step of separating the dummy areas D1 to D4 can separate the dummy area D1 as illustrated in FIG. 3 by cutting along the first cutting line I1 formed around the dummy areas D1 to D4 and the second cutting line I2 formed on both sides of the dummy areas D1 to D4 as illustrated in FIG. 2.

Referring to FIG. 3, the ceramic material 100 of the dummy area D1 can be divided into a portion 100a where the dummy pattern 220 is formed and a remaining portion 100b where the dummy pattern 220 is not formed. In such a case, the remaining portion 100b excluding the dummy pattern 220 can be fixed to a moving portion 22 of the measuring machine 20 illustrated in FIG. 6.

In the step of measuring the peel strength of the dummy pattern 220 formed in the separated dummy area D1, the measuring machine 20 for measuring the peel strength of the dummy pattern 220 may include a clamp portion 21 for pulling and peeling off the dummy pattern 220 and the moving portion 22 for moving the dummy area D1.

The moving portion 22 is a portion that slides left and right along a rail R, and is provided on the upper part thereof with a fixing member 22a. The fixing member 22a serves to prevent the dummy area D1 from moving by fixing the remaining portion 100b except for the dummy pattern 220.

After peeling off a part of the dummy pattern 220, the peeled part is fixed to the clamp portion 21 of the measuring machine 20, and while the dummy area D1 is moved, the dummy pattern 220 is pulled at an angle of 45° by using the clamp portion 21 to peel off the dummy pattern 220 at a constant speed, thereby measuring the peel strength of the dummy pattern 220. For example, the dummy pattern 220 can be peeled off at a speed of 50.8 mm/min; however, the present disclosure is not limited thereto.

In this way, the method for measuring the peel strength of the metal-bonded ceramic substrate 1 according to embodiments of the present disclosure measures the peel strength of the dummy pattern 220 by peeling off the dummy pattern 220 while being pulled with the measuring machine 20, so that the peel strength for the circuit pattern 210 formed with the same metal layer 200 as the dummy pattern 220 can be actually measured, thereby increasing the reliability of a measured value.

The above description is merely intended to illustratively describe the technical spirit of the present disclosure, and various changes and modifications can be made by those skilled in the art to which the present disclosure pertains without departing from the essential features of the present disclosure. Therefore, the embodiments disclosed in the present disclosure are not intended to limit the technical spirit of the present disclosure, but are intended to describe the present disclosure. The scope of the technical spirit of the present disclosure is not limited by these embodiments. The scope of the present disclosure should be interpreted by the accompanying claims and all technical spirits falling within the equivalent scope thereto should be interpreted as being included in the scope of the present disclosure.

1. A method for measuring peel strength of a metal-bonded ceramic substrate, comprising:
providing a metal-bonded ceramic substrate including a circuit pattern area where a plurality of circuit patterns are disposed in rows and columns and a plurality of dummy areas encompassing the circuit pattern area, a dummy pattern for measuring peel strength being formed in at least one of the dummy areas;
separating at least one of the dummy areas; and
measuring peel strength of the dummy pattern formed in the separated dummy area.

2. The method for measuring peel strength of a metal-bonded ceramic substrate of claim 1, wherein, in the measuring of the peel strength of the dummy pattern, a remaining portion of the separated dummy area except for the dummy pattern is fixed, and the dummy pattern is peeled off while being pulled with a measuring machine to measure the peel strength of the dummy pattern.

3. The method for measuring peel strength of a metal-bonded ceramic substrate of claim 1, wherein, in the separating of the dummy areas, the dummy areas are separated along a cutting line formed around the dummy areas.

4. The method for measuring peel strength of a metal-bonded ceramic substrate of claim 1, wherein, in the providing of the metal-bonded ceramic substrate, the dummy pattern is disposed to cross a central portion of the dummy area.

5. The method for measuring peel strength of a metal-bonded ceramic substrate of claim 1, wherein, in the providing of the metal-bonded ceramic substrate, the dummy pattern is formed in a bar shape.

6. The method for measuring peel strength of a metal-bonded ceramic substrate of claim 1, wherein, in the providing of the metal-bonded ceramic substrate, the dummy pattern has a length of 100 mm or more and a width of 2 mm or more.

7. The method for measuring peel strength of a metal-bonded ceramic substrate of claim 3, wherein, in the providing of the metal-bonded ceramic substrate, a first cutting line is formed between the circuit patterns, and between the circuit pattern and the dummy area.

8. The method for measuring peel strength of a metal-bonded ceramic substrate of claim 3, wherein, in the providing of the metal-bonded ceramic substrate, a second cutting line is formed on both sides of the dummy area, and is a portion corresponding to an extension line of a boundary between the circuit pattern and the dummy area.

9. A method for manufacturing a metal-bonded ceramic substrate, comprising:
providing a ceramic material; and
forming a plurality of circuit patterns in rows and columns on at least one surface of the ceramic material and forming a dummy pattern in at least one of a plurality of dummy areas encompassing an area where the circuit patterns are formed,
wherein in the forming of the dummy pattern, when the circuit pattern is formed in the area where the circuit patterns are formed, the dummy pattern for measuring peel strength is formed together in at least one of the plurality of dummy areas.

10. The method for manufacturing a metal-bonded ceramic substrate of claim 9, wherein, in the forming of the dummy pattern, the dummy pattern is disposed to cross a central portion of the dummy area.

11. The method for manufacturing a metal-bonded ceramic substrate of claim 9, wherein, in the forming of the dummy pattern, the dummy pattern is formed in a bar shape.

12. The method for manufacturing a metal-bonded ceramic substrate of claim 9, wherein, in the forming of the dummy pattern, the dummy pattern has a length of 100 mm or more and a width of 2 mm or more.

13. The method for manufacturing a metal-bonded ceramic substrate of claim 9, wherein the forming of the dummy pattern comprises:
bonding a metal layer to at least one surface of the ceramic material; and
forming the circuit patterns and the dummy pattern by etching the metal layer.

14. The method for manufacturing a metal-bonded ceramic substrate of claim 13, wherein the forming of the circuit patterns and the dummy pattern comprises:
forming a photoresist pattern on an upper surface of the metal layer; and
etching the metal layer by using the photoresist pattern as an etching mask.

15. A metal-bonded ceramic substrate including metal layers bonded to a surface of the metal-bonded ceramic substrate to form a plurality of circuit patterns disposed in rows and columns, wherein, when the circuit patterns are formed, a dummy pattern for measuring peel strength is formed together in at least one of a plurality of dummy areas encompassing an area where the circuit patterns are formed.

16. The metal-bonded ceramic substrate of claim 15, wherein the dummy pattern is disposed to cross a central portion of the dummy area.

17. The metal-bonded ceramic substrate of claim 15, wherein the dummy pattern is formed in a bar shape.

18. The metal-bonded ceramic substrate of claim 15, wherein the dummy pattern has a length of 100 mm or more and a width of 2 mm or more.

19. The metal-bonded ceramic substrate of claim 15, wherein a first cutting line is formed between the circuit patterns, and between the circuit pattern and the dummy area.

20. The metal-bonded ceramic substrate of claim 15, wherein a second cutting line is formed on both sides of the dummy area, and is a portion corresponding to an extension line of a boundary between the circuit pattern and the dummy area.
